(19) United States
(12) Patent Application Publication
(10) Pub. No.: US 2020/0034716 A1
(43) Pub. Date: Jan. 30, 2020

(54) GLOBAL OPTIMAL PARTICLE FILTERING METHOD AND GLOBAL OPTIMAL PARTICLE FILTER

(71) Applicants: Lin LI, Guangdong (CN); Yun LI, Guangdong (CN); Dongguan University of Technology, Guangdong (CN)

(72) Inventors: Lin LI, Guangdong (CN); Yun LI, Guangdong (CN)

(73) Assignees: Dongguan University of Technology, Guangdong (CN); Lin LI, Guangdong (CN); Yun LI, Guangdong (CN)

(21) Appl. No.: 16/335,675

(22) PCT Filed: Feb. 2, 2018
(86) PCT No.: PCT/CN2018/075151

§ 371 Date: Mar. 21, 2019

(30) Foreign Application Priority Data
Feb. 28, 2017 (CN) 201710114832.X

(51) Int. Cl. G06N 3/12; G06N 3/00

(52) U.S. Cl. CPC G06N 3/126; H03H 17/0257; G06N 3/006

(57) ABSTRACT

The invention relates to a global optimal particle filtering method and a global optimal particle filter. The problem of particle filter processing nonlinear and non-Gaussian signals is effectively solved. The main technical means is to use the Lamarck genetic natural law to construct a global optimal particle filter comprising: generating an initial particle set; using Unscented Kalman Filter to perform importance sampling on the initial particle set to obtain sampled particles; performing floating-point number encoding for each of the sampled particles to obtain an encoded particle set; setting an initial population; using the initial population as an original trial population to sequentially perform a Lamarck overwriting operation, a real number decoding operation, and an elite retention operation; using the real-number optimal candidate particle as a prediction sample for a next moment, and obtaining a state estimation value of a system. The invention is applicable to machine learning.

### TECHNICAL FIELD

The invention relates to a global optimal particle filtering method and a global optimal particle filter, which belongs to the field of signal processing.

### BACKGROUND

The state estimation problem of dynamic systems involves many fields, especially in the fields of signal processing, artificial intelligence and image processing, and it also has important application value in the fields such as navigation and guidance, information fusion, automatic control, financial analysis, intelligent monitoring and so on. Traditional Kalman filtering is only applicable to linear Gaussian systems, and extended Kalman filtering can only deal with the weak nonlinearity of the system. Therefore, particle filtering which is not limited by system model characteristics and noise distribution, has attracted much attention in the filtering problem of nonlinear and non-Gaussian dynamic systems.

Particle filtering is a filtering method based on Monte Carlo simulation and recursive Bayesian estimation. The basic principle is a process to obtain a state minimum variance estimation by finding a set of random samples propagating in the state space, namely “particles”, approximating the posterior probability density function, and replacing the integral operation with the sample mean. Common particle filtering algorithms include elementary particle filtering (PF), auxiliary particle filtering (APF), and regularized particle filtering (RPF).

The performance of particle filtering algorithms is limited by two major problems: particle degeneration and particle impoverishment. Particle degeneration means that as the number of iterations increases, the weight of the remaining particles is negligible except for a few particles having large weights. Particle impoverishment means that after resampling, large weight particles are assigned multiple times and the diversity of particle set is lost. The key technique to solve these two problems is the selection of the proposal distribution and the improvement of the resampling algorithm.

In recent years, researchers have tried to use intelligent optimization algorithms, such as genetic algorithm, particle swarm optimization algorithm, ant colony algorithm and artificial fish swarm algorithm and so on, to achieve the purposes of improving particle distribution and improving the performance of particle filtering, by optimizing search and retaining particles that can reflect the system probability density function. At present, there are still some shortcomings in the research of intelligent optimization particle filtering. On one hand, the existing research methods do not take into account the latest observations of the system state, resulting in large deviation between the sampled samples and the true posterior probability density samples. On the other hand, the proposed intelligent optimization algorithm still has some shortcomings in controlling the diversity of particles and the global guiding ability of the optimization process, and both increase the complexity and computational amount of particle filtering, which affects the optimization speed. Surrounding the above two problems, the present invention adopts the Unscented Kalman Filter (UKF) algorithm as the importance density function, and constructs a globally optimal particle filter by using the Lamarck genetic natural law.

### SUMMARY OF THE INVENTION

The object of the present invention is to solve the problems that the existing particle filtering algorithm causes a large deviation between the sampled sample and the true posterior probability density sample, and that the control ability of the particle diversity and the directing ability of optimizing process are insufficient, which increases the complexity and the computational amount of the particle filtering, and that the existing particle degeneration and particle impoverishment causes the disability in effective processing of the nonlinear and non-Gaussian signals, and thus to provide a global optimal particle filtering method and a global optimal particle filter.

A global optimal particle filtering method, characterized in that, the method comprises steps of:

Step 1: generating an initial particle set.

Step 2: using Unscented Kalman Filter to perform importance sampling on the initial particle set to obtain sampled particles.

Step 3: performing floating-point number encoding for each of the sampled particles to obtain an encoded particle set.

Step 4: setting an initial population according to the encoded particle set.

Step 5: using the initial population as an original trial population to sequentially perform a Lamarck overwriting operation, a real number decoding operation, and an elite retention operation; wherein the Lamarck overwriting operation refers to, according to a ratio between fitnesses of two parent candidate particles, passing a code of the parent with a higher fitness directly to an offspring of the parent with a lower fitness, replacing corresponding bits of its floating-point number, and retaining a parent particle with the higher fitness as its offspring particle; and finally obtaining a overwritten particle set; the real number decoding operation is to convert the particle set obtained by the Lamarck overwriting operation into a real-number particle set; the elite retention operation is to compare a weight of the particle having a largest weight in the candidate particle set which is selected from each iteration with a weight of the particle having a largest weight in the previous generation, to select the particle having a larger weight, and to replace both the particle having a smallest weight and its floating-point number format into the particle having the largest weight and its floating-point number format, generating a new generation of population and using the new generation of population as the original trial population.

Step 6: repeatedly performing step 5 until an iteration termination condition is reached; obtaining an optimal real-number particle set when terminated.

Step 7: using the optimal real-number particle set as a prediction sample for a next moment, and proceeding to step 2 until a system termination condition is reached, obtaining a state estimation value of a system.

The present invention further provides global optimal particle falterer, which comprises:

an initial particle set generating module, used for generating an initial particle set;

a sampling module, used for performing importance sampling on the initial particle set by using Unscented Kalman Filter to obtain sampled particles;

a floating-point number encoding module, used for performing floating-point number encoding for each of the sampled particles to obtain an encoded particle set;

an initial population setting module, used for setting an initial population according to the encoded particle set;

a Lamarck overwriting module used for using the initial population as an original trial population to sequentially perform a Lamarck overwriting operation, a real number decoding operation, and an elite retention operation, wherein the Lamarck overwriting operation refers to, according to a ratio between fitnesses of two parent candidate particles, passing a code of the parent with a higher fitness directly to an offspring of the parent with a lower fitness, replacing corresponding bits of its floating-point number, and retaining a parent particle with the higher fitness as its offspring particle; and finally obtaining a overwritten particle set; the real number decoding operation is to convert the particle set obtained by the Lamarck overwriting operation into a real-number particle set; the elite retention operation is to compare a weight of the particle having a largest weight in the candidate particle set which is selected from each iteration with a weight of the particle having a largest weight in the previous generation, to select the particle having a larger weight, and to replace both the particle having a smallest weight and its floating-point number format into the particle having the largest weight and its floating-point number format, generating a new generation of population and using the new generation of population as the original trial population;

an iteration control module, used for controlling the Lamarck overwriting module to repeatedly performing iteration until an iteration termination condition is reached; obtaining an optimal real-number particle set when terminated;

a state estimation value determining module, used for using the optimal real-number particle set as a prediction sample for a next moment, and proceeding to step 2 until a system termination condition is reached, obtaining a state estimation value.

The technical effects of the present invention are as follows.

The resampling method based on Lamarck genetics is designed to replace the traditional resampling method. By optimizing the particle set and increasing the particle diversity, the problem of particle degeneration in the traditional particle filtering algorithm is avoided, and the purpose of improving the filtering estimation accuracy is achieved. At the same time, the method maximally utilizes the information of the particle itself, improves the particle utilization rate and reduces the number of the used particles and the running time of the algorithm. Furthermore, the sampling process of optimization has a simple structure, less control parameters and lower computational complexity.

The present invention uses the Unscented Kalman Filter to generate the importance density function, incorporates more latest observation information, and improves the accuracy and stability of the generated predicted particles. Thus, the problem of particle degradation is effectively avoided, and a better state estimation accuracy is achieved in the environment with large observation noise.

The present invention incorporates Unscented Kalman Filter and use Lamarck genetic natural law to improve the global directing ability of the optimization process, to reduce the complexity and computational amount of particle filtering, and to construct a fast global optimal particle filter.

The present invention can be more widely applied to various fields, including 1) works required for complex systems such as nonlinear filtering, cluster analysis, pattern recognition, image processing, which can make complicated things with disordered surfaces to be systematic; 2) nonlinear filtering, self-adaptation, self-learning and self-organizing intelligent behaviors required by the automatic control system, which can adapt to environmental changes, reduce fluctuations, ensure high accuracy, and ensure real-time and rapid execution; 3) the design of the hardware and program which does not need to accurately tell the computer how to do it, but is automatically completed by the computer; 4) comprehensive application, which is combined with other technologies to respectively exerts their own strengths and comprehensively solves the problem. For example, the present system and the artificial neural network are combined with each other to solve problems such as noisy machine learning and machine reading.

The present invention has high accuracy and stability in various tests of the nonlinear target tracking model.

### BRIEF DESCRIPTION OF THE DRAWINGS

FIG. 1 is a flow chart of a global optimal particle filtering method of the present invention.

FIG. 2 is a schematic view of an embodiment of floating-point number encoding of the present invention.

FIG. 3 is a flow chart of an embodiment of step 5 of the present invention.

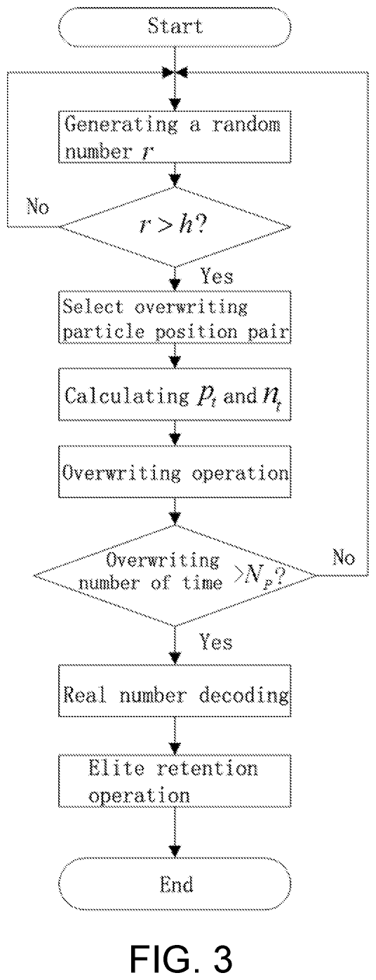

FIG. 4 is a schematic view of an overwriting operation in step 5 of the present invention.

FIG. 5 is a schematic curve showing a comparison between mean of root mean square errors of the methods of the present invention and those of other particle filtering algorithms when the number of particles is 10.

FIG. 6 is a schematic block diagram of the global optimal particle filter of the present invention.

### DETAILED DESCRIPTION OF THE PREFERRED EMBODIMENT

### Embodiment 1

A global optimal particle filtering method provided by the invention uses the particle to describe a state space of a dynamic system, and assumes that the state space model of the nonlinear dynamic system is:

xₖ=fₖ₋₁(xₖ₋₁, uₖ₋₁)

zₖ=hₖ(xₖ, vₖ)

wherein xₖ∈Rⁿ is a n-dimensional system state vector at a time k, zₖ∈R^{m} is the m-dimensional measurement vector at the time k; a transition map and a measurement map of the system state are fₖ₋₁(×):Rⁿ×Rⁿ→Rⁿ and hₖ(·):R^{m}×R^{m}→R^{m} respectively; a process noise and a measurement noise of the system are uₖ₋₁∈Rⁿ and vₖ∈R^{m} respectively.

It should be noted that the representation of the state space model of the nonlinear system is equivalent to the above formula, that is, those skilled in the art can think of that the formula representation of the nonlinear system is as shown in the above formula.

Firstly, an Unscented Kalman Filter algorithm is used to generate an importance function, and it is sampled to obtain sampled particles. Then, a Lamarck genetic resampling method is used to replace the traditional resampling process, and the sampled particles are optimized and propagated by using a Lamarck genetic overwriting operation and an elite retention operation; finally, an optimal particle point set is obtained, and a target estimation result is given. The method of the present invention performs floating-point number encoding on particles, and use the particle set in the floating-point number format as a population. Each particle in floating-point number format is used a code of a chromosome of the population, and each bit of floating-point number value of the particle is used as a decimal gene of the chromosome. The specific recursive process comprises the following operations:

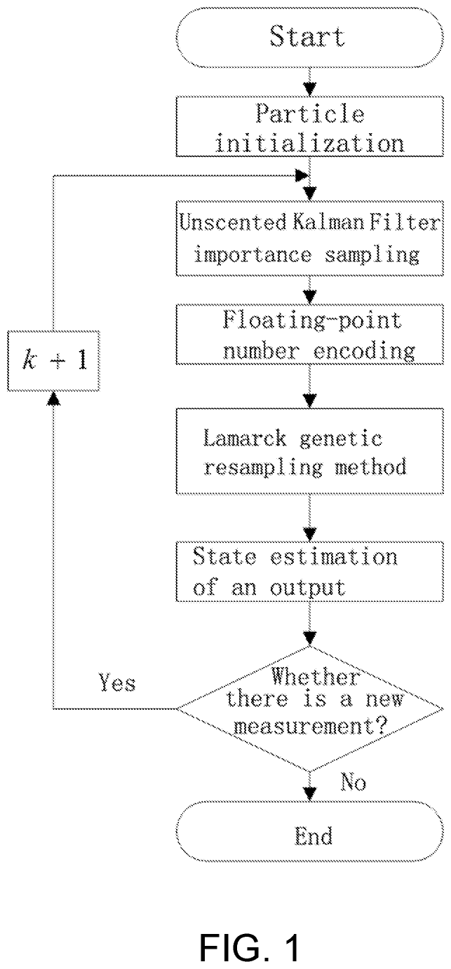

The nonlinear dynamic system signal processing system of this embodiment, as shown in FIG. 1, comprises the steps of:

Step 1: generating an initial set of particles. Specifically, step 1 may be as follows: generating the initial particle set {x₀ⁱ, i=1, 2, . . . , N} according to an initial proposal distribution p(x₀), wherein N is the total number of particles and i is a sequence number of the particle.

Step 2: using Unscented Kalman Filter to perform importance sampling on the initial particle set to obtain sampled particles {xₖⁱ, wₖⁱ}ᵢ₌₁^{N}, wherein k denotes that the sampled particle is a sample sampled at a time k.

Step 3: performing floating-point number encoding for each of the sampled particles to obtain an encoded particle set. The encoding method of this floating-point number can use the encoding method in cited references [1]-[3].

Step 4: setting an initial population according to the encoded particle set.

Step 5: using the initial population as an original trial population to sequentially perform a Lamarck overwriting operation, a real number decoding operation, and an elite retention operation; wherein the Lamarck overwriting operation refers to, according to a ratio between fitnesses of two parent candidate particles, passing a code of the parent with a higher fitness directly to an offspring of the parent with a lower fitness, replacing corresponding bits of its floating-point number, and retaining a parent particle with the higher fitness as its offspring particle; and finally obtaining a overwritten particle set; the real number decoding operation is to convert the particle set in floating-point number format obtained by the Lamarck overwriting operation into a real-number particle set; the elite retention operation is to compare a weight of the particle having a largest weight in the particle set which is selected from each iteration with a weight of the particle having a largest weight in the previous generation, to select the particle having a larger weight, and to replace both the particle having a smallest weight and its floating-point number format into the particle having the largest weight and its floating-point number format, generating a new generation of population and using the new generation of population as the original trial population.

Step 6: repeatedly performing step 5 until an iteration termination condition is reached; obtaining a real-number optimal particle set when terminated. Specifically, step 6 may be as follows: using the new generation of particle set in floating-point format as the original trial population for the overwriting operation, and repeatedly iterating step 5 until the termination condition is reached; finally, obtaining the optimal real-number particle set.

Step 7: using the optimal real-number particle set as a prediction sample for a next moment, and proceeding to step 2 until a system termination condition is reached, obtaining a state estimation value of a system.

### Embodiment 2

The present embodiment differs from embodiment 1 in that:

The initial particle set in step 1 is {x₀ⁱ, i=1, 2, . . . , N}, characterized in that, the step 2 is specifically as follows:

Step 2.1: calculating a mean \tilde{x}ⁱₖ and a variance Pₖⁱ of the initial particle set {x₀ⁱ, i=1, 2, . . . , N}, and obtaining a proposal distribution q(xₖⁱ|x_{0:k-1}ⁱ, z_{1;k})=N(\tilde{x}ₖⁱ, Pₖⁱ) of UKF; wherein the particle xₖⁱ satisfies xₖⁱ˜N(\tilde{x}ₖⁱ, Pₖⁱ).

Step 2.2: calculating the weight \tilde{w}ₖⁱ of the sampled particle xₖⁱ and normalizing it to obtain the normalized weight wₖⁱ, i.e.,

$${\tilde{w}}_{k}^{i} ∝ {\tilde{w}}_{k - 1}^{i} \frac{p ( {z}_{k} \vert {x}_{k}^{i} ) p ( {x}_{k}^{i} \vert {x}_{k - 1}^{i} )}{q ( {x}_{k}^{i} \vert {x}_{k - 1}^{i} , {z}_{k} )} , {w}_{k}^{i} = {\tilde{w}}_{k}^{i} / {\sum }_{i = 1}^{N} {\tilde{w}}_{k}^{i} .$$

Step 2.3: obtaining the sampled particles {xₖⁱ, wₖⁱ}ᵢ₌₁^{N} according to the particle xₖⁱ and its weight wₖⁱ.

The other steps and parameters are the same as those in embodiment 1.

### Embodiment 3

The present embodiment differs from embodiment 1 or 2 in that:

Step 3 is specifically as follows:

Representing the particle xₖⁱ as xₖⁱ=(nᵢ¹nᵢ² . . . nᵢ^{l})ₖ by the floating-point number format using a fixed number l of significant bits, and obtaining the encoded particle set {(nᵢ¹nᵢ² . . . nᵢ^{l})ₖ}ᵢ₌₁^{N}={(n₁¹n₁² . . . n₁^{l})ₖ, (n₂¹n₂² . . . n₂¹)ₖ, . . . , (n_{N}¹n_{N}² . . . n_{N}^{l})ₖ}, wherein n_{N}^{l} represents a value of a significant digit of the Nth particle.

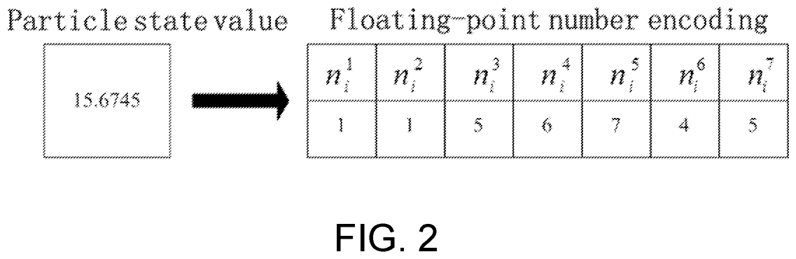

The first bit nᵢ¹ of the floating-point number value represents the sign bit. “1” represents a positive number and “0” represents a negative number. The fixed number l of significant bits is set by the pre-filtering range. It should be noted that in maltlab it is correct to four decimal places, and if the bits is less than l, the highest bit is 0. For example, the ith particle has a state value of 15.6745 at the time k, and then its floating-point number format is as shown in FIG. 2.

The other steps and parameters are the same as those in embodiment 1 or 2.

### Embodiment 4

The present embodiment differs from one of the embodiments 1-3 in that:

Step 4 is specifically as follows:

Using the encoded particle set {(nᵢ¹nᵢ² . . . nᵢ^{l})ₖ}ᵢ₌₁^{N} in the floating-point number format at a time k as the first generation of initial population of an entire optimization operation; a population size Nₚ of the initial population being equal to a number N of particles; using the floating-point number format (nᵢ¹nᵢ² . . . nᵢ^{l})ₖ of each particle as one gene, each bit of a floating-point number value representing a decimal gene, and the weight wₖⁱ of each particle representing a fitness function value of each chromosome.

The other steps and parameters are the same as those in one of embodiments 1-3.

### Embodiment 5

The present embodiment differs from one of embodiments 1-4 in that:

Step 5 comprising steps of: step 5A: the Lamarck overwriting operation; step 5B: the real number decoding operation; and step 5C: the elite retention operation; wherein step 5A specifically comprises steps of:

Step 5A.1: selecting a overwriting particle according to a overwriting probability h, wherein h∈(0,1]; randomly generating a random number r between (0,1], if r<h, selecting the overwriting particle, otherwise entering into a next loop; letting the i₁th particle and its floating-point number format (nᵢ_{₁}¹nᵢ_{₁}² . . . nᵢ_{₁}^{l})ₖ and the i₂th particle and its floating-point number format (nᵢ_{₂}¹nᵢ_{₂}² . . . nᵢ_{₂}^{l})ₖ to be selected as overwriting particles, and satisfying wₖⁱ^{₁}>wₖⁱ^{₂}. For example, take l=6, perform the selection step in this round of loop, and select the floating-point number format of the i₁th and the i₂th particles, i.e. (nᵢ_{₁}¹nᵢ_{₁}²nᵢ_{₁}³nᵢ_{₁}⁴nᵢ_{₁}⁵nᵢ_{₁}⁶)ₖ and (nᵢ_{₂}¹nᵢ_{₂}²nᵢ_{₂}³nᵢ_{₂}⁴nᵢ_{₂}⁵nᵢ_{₂}⁶)ₖ, and the weight relationship is wₖⁱ^{₁}=2wₖⁱ^{₂}.

Step 5A.2: calculating a proportion pₜ of delivered genes, pₜ satisfying

$${p}_{t} = ( \frac{{w}_{k}^{{i}_{1}}}{{w}_{k}^{{i}_{1}} + {w}_{k}^{{i}_{2}}} )$$

and calculating a number nₜ of the delivered genes according to the following formula:

nₜ=l×pₜ=4

Step 5A.3: if not all the weights of the selected overwriting particles being 0, using the floating-point number format of the i₁th particle having the larger weight to overwriting the floating-point number format of the i₂th particle having a smaller weight, wherein an overwriting position is random, and a number of overwriting position is nₜ.

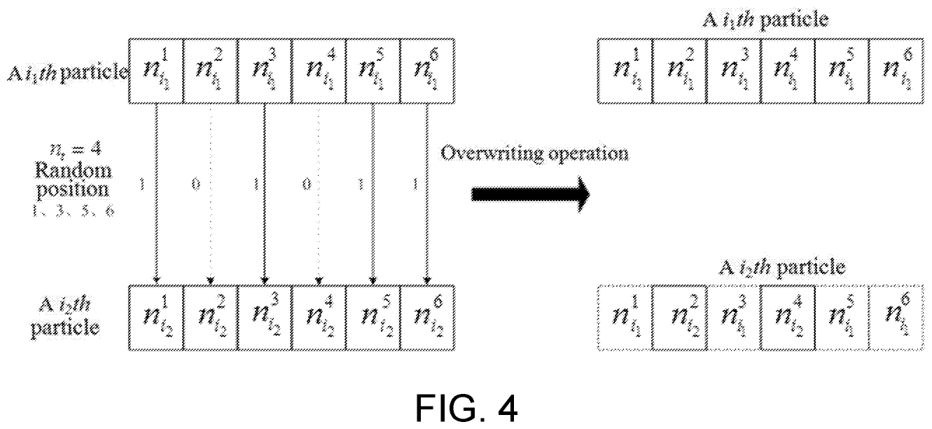

For example, when l=6, the floating-point number format of the i₂th particle is overwritten by the floating-point number format of the i₁th particle, wherein the position of the overwriting gene is random, and the first, third, fifth, and sixth bits are selected. An example of one overwriting operation in the algorithm of the present invention is as shown in FIG. 4. Then, the floating-point number format of the i₁th particle in the overwritten population is unchanged, and the floating-point number format of the i₂th particle is (nᵢ_{₁}¹nᵢ_{₂}²nᵢ_{₁}³nᵢ_{₂}⁴nᵢ_{₁}⁵nᵢ_{₁}⁶)ₖ. In this way, after the overwriting operation, the particles with a small weight are corrected by the particles with a large weight. If both of the two selected particles have the weight of 0, the process is not performed.

Step 5A.4: repeatedly performing steps 5A.1 to 5A.3 until a predetermined number N_{P} of times is reached to obtain a final overwritten particle set in the floating-point format:

{((nᵢ¹)′(nᵢ²)′ . . . (nᵢ^{l})′)ₖ}ᵢ₌₁^{N}={((n₁¹)′(n₁²)′ . . . (n₁^{l})′)ₖ, . . . , ((n_{N}¹)′(n_{N}²)′ . . . (n_{N}^{l})′)ₖ}.

The other steps and parameters are the same as those in embodiments 1-4.

### Embodiment 6

The present embodiment differs from one of the embodiments 1-5 in that:

Step 5B specifically comprises steps of:

performing the real number decoding on the particle set in the floating-point format obtained in step 5A to obtain the particle set {x′ₖⁱ}ᵢ₌₁^{N}, wherein

x′ₖⁱ=(−1)⁽ⁿ^{ᵢ}^{¹}^{)′}×(10^{(l-6)}×(nᵢ¹)′+10^{(l-7)}×(nᵢ²)′+10^{(l-8)}×(nᵢ³)′+ . . . +10⁻⁴×(nᵢ^{l})′), and

obtains the normalized weight w′ₖⁱ of the corresponding particle according to the real-number the particle.

x′ₖⁱ is the overwritten particle, and (nᵢ^{l})′ is the overwritten value of the ith significant bit of the ith particle.

The other steps and parameters are the same as those in one of embodiments 1-5.

### Embodiment 7

The present embodiment differs from one of embodiments 1-6 in that:

Step 5C specifically comprises:

selecting the real-number particle having the largest weight in the current iteration, and then comparing its weight with the weight of the particle having the largest weight in the previous iteration, selecting the particle having the larger weight, replacing both the particle having the smallest weight and its floating-point number format into the particle having the largest weight and its floating-point number format, generating the new generation of population.

The other steps and parameters are the same as those in one of embodiments 1-6.

### Embodiment 8

The present embodiment differs from one of embodiments 1-7 in that:

In step 5C, a gth generation of population is denoted as S(g)={s₁(g), s₂(g), . . . , s_{N}_{ₛ}(g)}, wherein sᵢ(g) represents an optimal individual in the gth generation of population; 1≤i≤Nₛ; and Nₛ is a size of the population; a new generation of population being S(g+1)={s₁(g+1), . . . , s_{N}_{ₛ}(g+1)}, wherein an optimal individual in the new generation of population is sⱼ(g+1); a worst individual in the new generation of population is sₘ(g+1), 1≤j≤Nₛ, and 1≤m≤Nₛ,

wherein if sᵢ(g) is superior to sⱼ(g+1), then the optimal individual sᵢ(g) in the gth generation of population is added into the new population S(g+1) as a (Nₛ+1)th individual of the new population S(g+1), and the individual having the smallest fitness is removed from the new population S(g+1); at this time, the new population S(g+1) is represented as:

S(g+1)={s₁(g+1), . . . , sₘ₋₁(g+1), sᵢ(g), sₘ₊₁(g+1) . . . , s_{N}_{ₛ}(g+1)}

wherein if sᵢ(g) is not superior to sⱼ(g+1) then the new population S(g+1) remain the same, a new generation of particle set {x″ₖⁱ, w″ₖⁱ}ᵢ₌₁^{N} is obtained, the particle set in floating-point format is {((nᵢ¹)″(nᵢ²)″ . . . (nᵢ^{l})″)ₖ}ᵢ₌₁^{N}.

According to the above performing steps, the optimal real-number particle set {\tilde{x}ₖⁱ, 1/N}ᵢ₌₁^{N} with equal weight is finally obtained in step 7. The system state estimation is as follows:

$${\hat{x}}_{k} = \frac{1}{N} {\sum }_{i = 1}^{N} {\tilde{x}}_{k}^{i}$$

And use the generated optimal particle set as a prediction sample of a next moment and proceeding to step 2.

It should be noted that the population corresponds to the particle set, and the individuals in the population correspond to the particles in the particle group.

### Embodiment 9

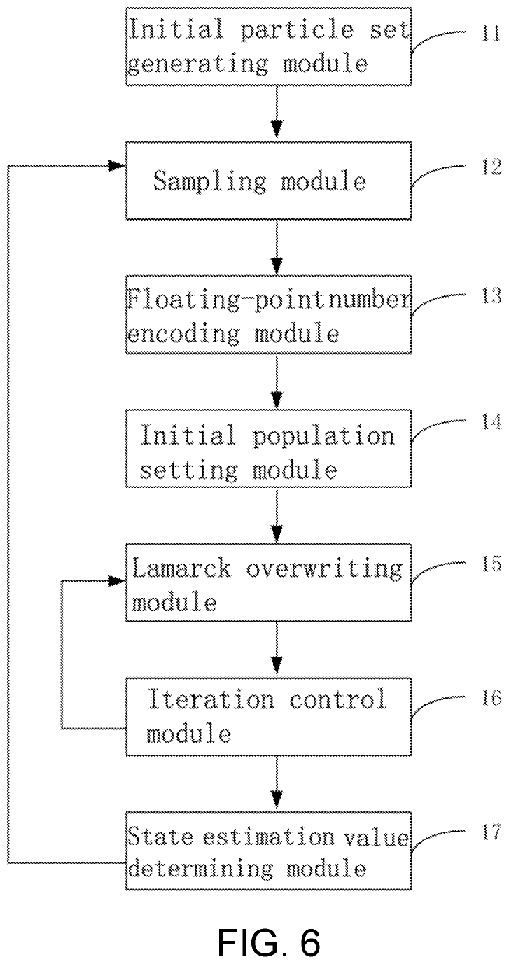

The present embodiment provides a global optimal particle falterer, as shown in FIG. 6, which comprises:

an initial particle set generating module 11, used for generating an initial particle set;

a sampling module 12, used for performing importance sampling on the initial particle set by using Unscented Kalman Filter to obtain sampled particles;

a floating-point number encoding module 13, used for performing floating-point number encoding for each of the sampled particles to obtain an encoded particle set;

an initial population setting module 14, used for setting an initial population according to the encoded particle set;

a Lamarck overwriting module 15, used for using the initial population as an original trial population to sequentially perform a Lamarck overwriting operation, a real number decoding operation, and an elite retention operation, wherein the Lamarck overwriting operation refers to, according to a ratio between fitnesses of two parent candidate particles, passing a code of the parent with a higher fitness directly to an offspring of the parent with a lower fitness, replacing corresponding bits of its floating-point number, and retaining a parent particle with the higher fitness as its offspring particle; and finally obtaining a overwritten particle set; the real number decoding operation is to convert the particle set obtained by the Lamarck overwriting operation into a real-number particle set; the elite retention operation is to compare a weight of the particle having a largest weight in the candidate particle set which is selected from each iteration with a weight of the particle having a largest weight in the previous generation, to select the particle having a larger weight, and to replace both the particle having a smallest weight and its floating-point number format into the particle having the largest weight and its floating-point number format, generating a new generation of population and using the new generation of population as the original trial population;

an iteration control module 16, used for controlling the Lamarck overwriting module 15 to repeatedly performing iteration until an iteration termination condition is reached; obtaining an optimal real-number particle set when terminated.

a state estimation value determining module 17, used for using the optimal real-number particle set as a prediction sample for a next moment, and sending sampling signal to sampling module 12 until a system termination condition is reached, obtaining a state estimation value.

The present embodiment is completely corresponding to the embodiment 1, and the principle is not described in detail herein.

### EXAMPLE 1

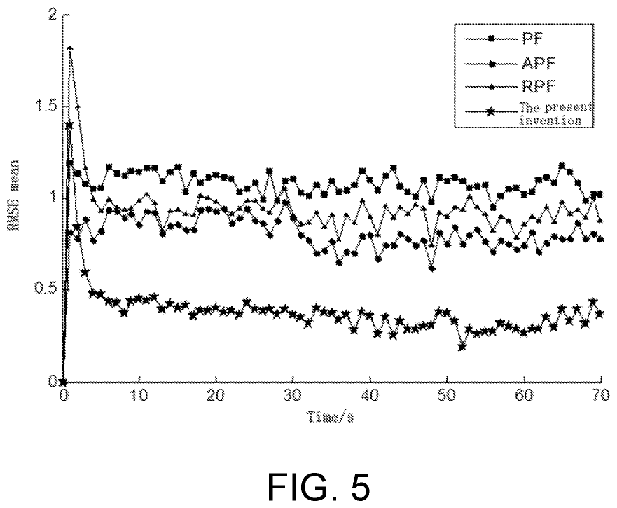

The present embodiment compares the present invention with several other particle filtering algorithms by state estimation of one nonlinear dynamic system. The state space model of the system is as follows:

$${x}_{k + 1} = 1 + sin ( 0.04 π k ) + 0.5 {x}_{k} + {v}_{k}$$

$${z}_{k} = \{ \begin{matrix}0.2 {x}_{k}^{2} + {n}_{k} & k \leq 30 \\ 0.5 {x}_{k} - 2 + {n}_{k} & k > 30\end{matrix}$$

wherein a process noise is vₖ˜Gamma(3,2) and an observation noise is nₖ˜N(0,0.00001). Set the observation time to be 70, the number of runs to be 200, and the number of particles N to be 10, 100, and 200, respectively. The parameters of the algorithm of the present invention are set as follows: G=20, h=0.9, l=6. When the number of particles N is 10, a root mean square error (RMSE) mean generated by the algorithm proposed by the present invention and those generated by other particle filtering algorithms are shown in FIG. 5.

As can be seen from FIG. 5, the RMSE mean of the algorithm of the present invention at the same number of particles is significantly better than those of other algorithms.

For the example, 200 Monte Carlo experiments were performed with the number of particles N=10, N=100, N=500 respectively, and the RMSE mean, RMSE variance and average run time were counted. The results are shown in Table 1, Table 2 and Table 3 as follows:

TABLE 1
Test results with N of 10

| Algorithm | RMSE mean | RMSE variance | run time(s) |
|---|---|---|---|
| PF | 1.0790 | 0.0165 | 0.0164 |
| APF | 0.8090 | 0.0134 | 0.1270 |
| RPF | 0.9521 | 0.0118 | 0.0334 |
| The present | 0.4059 | 0.0043 | 0.2432 |
| invention | | | |

TABLE 2
Test results with N of 100

| Algorithm | RMSE mean | RMSE variance | run time(s) |
|---|---|---|---|
| PF | 0.7150 | 0.0162 | 0.1250 |
| APF | 0.5888 | 0.0132 | 9.9471 |
| RPF | 0.6184 | 0.0119 | 0.2449 |
| The present | 0.077 | 0.0042 | 2.0714 |
| invention | | | |

TABLE 3
Test results with N of 200

| Algorithm | RMSE mean | RMSE variance | run time(s) |
|---|---|---|---|
| PF | 0.6539 | 0.0194 | 0.2483 |
| APF | 0.4996 | 0.0144 | 39.6517 |
| RPF | 0.5836 | 0.0113 | 0.4840 |
| The present | 0.0180 | 0.0008 | 4.1612 |
| invention | | | |

It can be seen from the statistics of Table 1, Table 2 and Table 3 that:

1) When the number of particles is the same, although the invention runs longer than other particle filtering methods, its tracking accuracy is much higher than that of other particle filtering methods; especially when the number of particles is 100 and 200, the mean of tracking root mean square error of the present invention is far less than those of other particle filtering methods.

2) When the number of particles is 200, the tracking performance of the other three particle filtering methods is not as good as that of the present invention, that is to say, the particle utilization ratio of the present invention is higher than those of other particle filtering methods.

3) The tracking accuracy of the present invention is far superior to that of other particle filtering algorithms in the case of equivalent time used.

4) With different number of particles, the variance of the tracking root mean square error of the present invention is less than those of other particle filtering algorithms, indicating that the present invention has a better stability.

In summary, the present invention has relatively high accuracy and stability in the nonlinear target tracking model.

### REFERENCES

[1] Tan K C, Li Y. Evolutionary L∞ identification and model reduction for robust control[J]. Journal of Systems and Control Engineering, 2000, 214(3):231-238.

[2] Tan K C, Li Y. Performance-based control system design automation via evolutionary computing[J]. Engineering Applications of Artificial Intelligence, 2001, 14(4):473-486.

[3] Li Y., K. C. Tan and M. Gong. Model Reduction in Control Systems by Means of Global Structure Evolution and Local Parameter Learning. In Evolutionary Algorithms in Engineering Applications, Springer-Verlag, Berlin, Germany, 1996.

There may be various other embodiments of the present invention. And various corresponding changes and modifications can be made by those skilled in the art according to the present invention without departing from the spirit and scope of the present invention. However, these corresponding changes and modifications intended to fall within the scope of the appended claims of the present invention.

1. A global optimal particle filtering method, the method comprises steps of:
step 1: generating an initial particle set;
step 2: using an Unscented Kalman Filter to perform an importance sampling on the initial particle set to obtain sampled particles;
step 3: performing a floating-point number encoding for each of the sampled particles to obtain an encoded particle set;
step 4: setting an initial population according to the encoded particle set;
step 5: using the initial population as an original trial population to sequentially perform a Lamarck overwriting operation, a real number decoding operation, and an elite retention operation; wherein the Lamarck overwriting operation refers to, according to a ratio between fitnesses of two parent candidate particles, passing a code of the parent with a higher fitness directly to an offspring of the parent with a lower fitness, replacing corresponding bits of its floating-point number, and retaining a parent particle with the higher fitness as its offspring particle; and finally obtaining a overwritten particle set; the real number decoding operation is to convert the particle set obtained by the Lamarck overwriting operation into a real-number particle set; the elite retention operation is to compare a weight of the particle having a largest weight in a candidate particle set which is selected from each iteration with a weight of the particle having a largest weight in the previous generation, to select the particle having a larger weight, and to replace both the particle having a smallest weight and its floating-point number format into the particle having the largest weight and its floating-point number format, generating a new generation of population and using the new generation of population as the original trial population;
step 6: repeatedly performing step 5 until an iteration termination condition is reached; obtaining an optimal real-number particle set when terminated;
step 7: using the optimal real-number particle set as a prediction sample for a next moment, and proceeding to step 2 until a system termination condition is reached, obtaining a state estimation value of a system.

2. The method according to claim 1, the initial particle set in the step 1 is {x₀ⁱ, i=1, 2, . . . , N}, wherein step 2 is specifically as follows:
step 2.1: calculating a mean \tilde{x}ₖⁱ and a variance Pₖⁱ of the initial particle set {x₀ⁱ, i=1, 2, . . . , N}, and obtaining a proposal distribution q(xₖⁱ|x_{0:k-1}ⁱ, z_{1;k})=N(\tilde{x}ₖⁱ, Pₖⁱ) of the Unscented Kalman Filter; wherein the particle xₖⁱ satisfies xₖⁱ˜N(\tilde{x}ₖⁱ, Pₖⁱ);
step 2.2: calculating a weight \tilde{w}ₖⁱ of the sampled particle xₖⁱ and normalizing it to obtain a normalized weight wₖⁱ, i.e.,
$${\tilde{w}}_{k}^{i} ∝ {\tilde{w}}_{k - 1}^{i} \frac{p ( {z}_{k} \vert {x}_{k}^{i} ) p ( {x}_{k}^{i} \vert {x}_{k - 1}^{i} )}{q ( {x}_{k}^{i} \vert {x}_{k - 1}^{i} , {z}_{k} )} ,$$
wₖⁱ=\tilde{w}ₖⁱ/Σᵢ₌₁^{N}\tilde{w}ₖⁱ
step 2.3: obtaining the sampled particles {xₖⁱ, wₖⁱ}ᵢ₌₁^{N} according to the particle xₖⁱ and its weight wₖⁱ.

3. The method according to claim 1, wherein step 3 is specifically as follows:
representing the particle xₖⁱ as xₖⁱ=(nᵢ¹nᵢ² . . . nᵢ^{l})ₖ by the floating-point number format using a fixed number l of significant bits, and obtaining the encoded particle set {(nᵢ¹nᵢ² . . . nᵢ^{l})ₖ}i=1^{N}={(n₁¹n₁² . . . n₁¹)ₖ, (n₂¹n₂² . . . n₂^{l})ₖ, . . . , (n_{N}¹n_{N}² . . . n_{N}^{l})ₖ}, wherein n_{N}^{l} represents a value of a number of significant bits of an Nth particle.

4. The method according to claim 3, wherein step 4 is specifically as follows:
using the encoded particle set {(nᵢ¹nᵢ² . . . nᵢ^{l})ₖ}ᵢ₌₁^{N} in the floating-point number format at a time k as a first generation of initial population of an entire optimization operation; a population size N_{P} of the initial population being equal to a number N of particles; using the floating-point number format (nᵢ¹nᵢ² . . . nᵢ^{l})ₖ of each particle as one individual, each bit of a floating-point number value representing one decimal gene, and the weight wₖⁱ of each particle representing a fitness function value of each chromosome.

5. The method according to claim 4, wherein step 5 comprises steps of:
step 5A: the Lamarck overwriting operation;
step 5B: the real number decoding operation; and
step 5C: the elite retention operation;
wherein step 5A specifically comprises steps of:
step 5A.1: for each particle, determining whether to select the particle as a overwriting particle according to a generated overwriting probability h, wherein h∈(0,1]; randomly generating a random number r between (0,1], if r<h, selecting the overwriting particle, otherwise not selecting the overwriting particle; letting a i₁th particle and its floating-point number format (nᵢ_{₁}¹nᵢ_{₁}² . . . nᵢ_{₁}^{l})ₖ and a i₂th particle and its floating-point number format (nᵢ_{₂}¹nᵢ_{₂}² . . . nᵢ_{₂}^{l})ₖ to be selected as overwriting particles, and satisfying wₖⁱ^{₁}>wₖⁱ^{₂};
step 5A.2: calculating a proportion pₜ of delivered genes, pₜ satisfying
$${p}_{t} = ( \frac{{w}_{k}^{{i}_{1}}}{{w}_{k}^{{i}_{1}} + {w}_{k}^{{i}_{2}}} )$$
and calculating a number nₜ of the delivered genes according to the following formula:
nₜ=l×pₜ
step 5A.3: if not all the weights of the selected overwriting particles being 0, then using the floating-point number format of the i₁th particle having the larger weight to overwriting the floating-point number format of the i₂th particle having a smaller weight, wherein an overwriting position is random, and a number of the overwriting position is nₜ;
step 5A.4: repeatedly performing steps 5A.1 to 5A.3 until a predetermined number N_{P} of times is reached to obtain a final overwritten particle set in the floating-point format:
{((nᵢ¹)′(nᵢ²)′ . . . (nᵢ^{l})′)ₖ}ᵢ₌₁^{N}={((n₁¹)′(n₁²)′ . . . (n₁^{l})′)ₖ, . . . , ((n_{N}¹)′(n_{N}²)′ . . . (n_{N}^{l})′)ₖ}.

6. The method according to claim 5, wherein step 5B specifically comprises steps of:
performing the real number decoding on the particle set in the floating-point format obtained in step 5A to obtain a written real-number particle set {x′ₖⁱ}ᵢ₌₁^{N}, wherein
x′ₖⁱ=(−1)⁽ⁿ^{ᵢ}^{¹}^{)′}×(10^{(l-6)}×(nᵢ¹)′+10^{(l-7)}×(nᵢ²)′+10^{(l-8)}×(nᵢ³)′+ . . . +10⁻⁴×(nᵢ^{l})′),
and obtaining the normalized weight w′ₖⁱ of corresponding particle according to the real-number particle.

7. The method according to claim 6, wherein step 5C specifically comprises:
selecting the real-number particle having the largest weight in the current iteration, and then comparing its weight with the weight of the particle having the largest weight in the previous iteration, selecting the particle having the larger weight, replacing both the particle having the smallest weight and its floating-point number format into the particle having the largest weight and its floating-point number format, generating the new generation of population and using the new generation of population as the original trial population.

8. The method according to claim 7, wherein in step 5C, a gth generation of population is denoted as S(g)={s₁(g), s₂(g), . . . , s_{N}_{ₛ}(g)}, wherein sᵢ(g) represents an optimal individual in the gth generation of population; 1≤i≤Nₛ; and Nₛ is the population size; a new generation of population being S(g+1)={s₁(g+1), . . . , s_{N}_{ₛ}(g+1)}, wherein the optimal individual in the new generation of population is sⱼ(g+1); a worst individual in the new generation of population is sₘ(g+1), 1≤j≤Nₛ, and 1≤m≤Nₛ,
wherein if sᵢ(g) is superior to sⱼ(g+1), then the optimal individual sᵢ(g) in the gth generation of population is added into the new population S(g+1) as a (Nₛ+1)th individual of the new population S(g+1) , and the individual having a smallest fitness is removed from the new population S(g+1) ; at this time, the new population S(g+1) is represented as:
S(g+1)={s₁(g+1), . . . , sₘ₋₁(g+1), sᵢ(g), sₘ₊₁(g+1) . . . , s_{N}_{ₛ}(g+1)}
wherein if sᵢ(g) is not superior to sⱼ(g+1), then the new population S(g+1) remain the same, a new generation of particle set {x″ₖⁱ, w″ₖⁱ}ᵢ₌₁^{N} is obtained, the particle set in floating-point format is {((nᵢ¹)″(nᵢ²)″ . . . (nᵢ^{l})″)ₖ}ᵢ₌₁^{N}.

9. A global optimal particle filterer, the global optimal particle filterer comprises:
an initial particle set generating module, used for generating an initial particle set;
a sampling module, used for performing importance sampling on the initial particle set by using Unscented Kalman Filter to obtain sampled particles;
a floating-point number encoding module, used for performing floating-point number encoding for each of the sampled particles to obtain an encoded particle set;
an initial population setting module, used for setting an initial population according to the encoded particle set;
a Lamarck overwriting module, used for using the initial population as an original trial population to sequentially perform a Lamarck overwriting operation, a real number decoding operation, and an elite retention operation, wherein the Lamarck overwriting operation refers to, according to a ratio between fitnesses of two parent candidate particles, passing a code of the parent with a higher fitness directly to an offspring of the parent with a lower fitness, replacing corresponding bits of its floating-point number, and retaining a parent particle with the higher fitness as its offspring particle; and finally obtaining a overwritten particle set; the real number decoding operation is to convert the particle set obtained by the Lamarck overwriting operation into a real-number particle set; the elite retention operation is to compare a weight of the particle having a largest weight in the candidate particle set which is selected from each iteration with a weight of the particle having a largest weight in the previous generation, to select the particle having a larger weight, and to replace both the particle having a smallest weight and its floating-point number format into the particle having the largest weight and its floating-point number format, generating a new generation of population and using the new generation of population as the original trial population;
an iteration control module, used for controlling the Lamarck overwriting module to repeatedly performing iteration until an iteration termination condition is reached; obtaining an optimal real-number particle set when terminated; a state estimation value determining module, used for using the optimal real-number particle set as a prediction sample for a next moment, and proceeding to step 2 until a system termination condition is reached, obtaining a state estimation value.

10. The method according to claim 2, wherein step 3 is specifically as follows:
representing the particle xₖⁱ as xₖⁱ=(nᵢ¹nᵢ² . . . nᵢ^{l})ₖ by the floating-point number format using a fixed number l of significant bits, and obtaining the encoded particle set {(nᵢ¹nᵢ² . . . nᵢ^{l})ₖ}ᵢ₌₁^{N}={(n₁¹n₁² . . . n₁^{l})ₖ, (n₂¹n₂² . . . n₂^{l})ₖ, . . . , (n_{N}¹n_{N}² . . . n_{N}^{l})ₖ}, wherein n_{N}^{l} represents a value of a number of significant bits of an Nth particle.

11. The method according to claim 10, wherein step 4 is specifically as follows:
using the encoded particle set {(nᵢ¹nᵢ² . . . nᵢ^{l})ₖ}ᵢ₌₁^{N} in the floating-point number format at a time k as a first generation of initial population of an entire optimization operation; a population size N_{P} of the initial population being equal to a number N of particles; using the floating-point number format (nᵢ¹nᵢ² . . . nᵢ^{l})ₖ of each particle as one individual, each bit of a floating-point number value representing one decimal gene, and the weight wₖⁱ of each particle representing a fitness function value of each chromosome.

12. The method according to claim 11, wherein step 5 comprises steps of:
step 5A: the Lamarck overwriting operation;
step 5B: the real number decoding operation; and
step 5C: the elite retention operation;
wherein step 5A specifically comprises steps of:
step 5A.1: for each particle, determining whether to select the particle as a overwriting particle according to a generated overwriting probability h, wherein h∈(0,1]; randomly generating a random number r between (0,1], if r<h, selecting the overwriting particle, otherwise not selecting the overwriting particle; letting a i₁th particle and its floating-point number format (nᵢ_{₁}¹nᵢ_{₁}² . . . nᵢ_{₁}^{l})ₖ and a i₂th particle and its floating-point number format (nᵢ_{₂}¹nᵢ_{₂}² . . . nᵢ_{₂}^{l})ₖ to be selected as overwriting particles, and satisfying wₖⁱ^{₁}>wₖⁱ^{₂};
step 5A.2: calculating a proportion pₜ of delivered genes, pₜ satisfying
$${p}_{t} = ( \frac{{w}_{k}^{{i}_{1}}}{{w}_{k}^{{i}_{1}} + {w}_{k}^{{i}_{2}}} )$$
and calculating a number nₜ of the delivered genes according to the following formula:
nₜ=l×pₜ
step 5A.3: if not all the weights of the selected overwriting particles being 0, then using the floating-point number format of the i₁th particle having the larger weight to overwriting the floating-point number format of the i₂th particle having a smaller weight, wherein an overwriting position is random, and a number of the overwriting position is nₜ;
step 5A.4: repeatedly performing steps 5A.1 to 5A.3 until a predetermined number N_{P} of times is reached to obtain a final overwritten particle set in the floating-point format:
{((nᵢ¹)′(nᵢ²)′ . . . (nᵢ^{l})′)ₖ}ᵢ₌₁^{N}={((n₁¹)′(n₁²)′ . . . (n₁^{l})′)ₖ, . . . , ((n_{N}¹)′(n_{N}²)′ . . . (n_{N}^{l})′)ₖ}.

13. The method according to claim 12, wherein step 5B specifically comprises steps of:
performing the real number decoding on the particle set in the floating-point format obtained in step 5A to obtain a written real-number particle set {x′ₖⁱ}ᵢ₋₁^{N}, wherein
x′ₖⁱ=(−1)⁽ⁿ^{ᵢ}₁^{)′}(10^{(l-6)}×(nᵢ¹)′+10^{(l-7)}×(nᵢ²)′+10^{(l-8)}×(nᵢ³)′+ . . . +10⁻⁴×(nᵢ^{l})′),
and obtaining the normalized weight w′ₖⁱ of corresponding particle according to the real-number particle.

14. The method according to claim 13, wherein step 5C specifically comprises:
selecting the real-number particle having the largest weight in the current iteration, and then comparing its weight with the weight of the particle having the largest weight in the previous iteration, selecting the particle having the larger weight, replacing both the particle having the smallest weight and its floating-point number format into the particle having the largest weight and its floating-point number format, generating the new generation of population and using the new generation of population as the original trial population.

15. The method according to claim 14, wherein in step 5C, a gth generation of population is denoted as, S(g)={s₁(g), s₂(g), . . . , s_{N}_{ₛ}(g)}, wherein sᵢ(g) represents an optimal individual in the gth generation of population; 1≤i≤Nₛ; and Nₛ is the population size; a new generation of population being S(g+1)={s₁(g+1), . . . , s_{N}_{ₛ}(g+1)}, wherein the optimal individual in the new generation of population is sⱼ(g+1); a worst individual in the new generation of population is sₘ(g+1), 1≤j≤Nₛ, and 1≤m≤Nₛ,
wherein if sᵢ(g) is superior to sⱼ(g+1), then the optimal individual sᵢ(g) in the gth generation of population is added into the new population S(g+1) as a (Nₛ+1)th individual of the new population S(g+1), and the individual having a smallest fitness is removed from the new population S(g+1); at this time, the new population S(g+1) is represented as: S(g+1)={s₁(g+1), . . . , sₘ₋₁(g+1), sᵢ(g), sₘ₊₁(g+1) . . . , s_{N}_{ₛ}(g+1)}
wherein if sᵢ(g) is not superior to sⱼ(g+1), then the new population S(g+1) remain the same, a new generation of particle set {x″ₖⁱ, w″ₖⁱ}ᵢ₌₁^{N} is obtained, the particle set in floating-point format is {((nᵢ¹)″(nᵢ²)″ . . . (nᵢ^{l})″)ₖ}ᵢ₌₁^{N}.
